(19) United States
(12) Patent Application Publication
(10) Pub. No.: US 2025/0053077 A1
(43) Pub. Date: Feb. 13, 2025

(54) MASK BLANK, METHOD FOR MANUFACTURING TRANSFER MASK, AND METHOD FOR MANUFACTURING SEMICONDUCTOR DEVICE

(71) Applicant: HOYA CORPORATION, Tokyo (JP)

(72) Inventors: Osamu NOZAWA, Tokyo (JP); Yasutaka HORIGOME, Tokyo (JP)

(73) Assignee: HOYA CORPORATION, Tokyo (JP)

(21) Appl. No.: 18/711,293

(22) PCT Filed: Nov. 25, 2022
(86) PCT No.: PCT/JP2022/043485

§ 371 Date: May 17, 2024

(30) Foreign Application Priority Data
Dec. 23, 2021 (JP) 2021-209071
Oct. 25, 2022 (JP) 2022-170315

(51) Int. Cl. G03F 1/50; H01L 21/027

(52) U.S. Cl. CPC G03F 1/50; H01L 21/027

(57) ABSTRACT

Provided is a mask blank having a structure in which a pattern-forming thin film, a first hard mask film, and a second hard mask film are stacked in this order on a main surface of a substrate. The pattern-forming thin film contains at least one element selected from silicon and transition metals. The first hard mask film contains chromium. The second hard mask film contains tantalum. The tantalum of the second hard mask film contains tantalum that is unsaturated with oxygen. The thickness of the pattern-forming thin film is 20 nm or more. The thickness of the first hard mask film is 15 nm or less. The thickness of the second hard mask film is 10 nm or less.

### CROSS-REFERENCE TO RELATED APPLICATIONS

This application is a National Stage of International Application No. PCT/JP2022/043485, which claims priority to Japanese Patent Application No. 2021-209071 filed Dec. 23, 2021 and Japanese Patent Application No. 2022-170315 filed Oct. 25, 2022, the contents of which are incorporated herein by reference in their entirety.

### TECHNICAL FIELD

The present disclosure relates to a mask blank, a method for manufacturing a transfer mask, and a method for manufacturing a semiconductor device.

### BACKGROUND OF THE DISCLOSURE

For a mask blank used in manufacturing a transfer mask, there is a known technique of providing a hard mask film for the purpose of miniaturization of a pattern to be formed on a transfer mask. For example, Patent Literature 1 mentioned below describes “a photomask blank including a transparent substrate with a light-shielding film and an etching mask film (hard mask film) sequentially formed on the transparent substrate, wherein the light-shielding film comprises at least a light-shielding layer containing a transition metal silicide and a surface-reflection preventing layer formed on the light-shielding layer and mainly composed of a tantalum compound containing at least one of oxygen and nitrogen and wherein the etching mask film comprises a chromium compound containing at least one of oxygen and nitrogen.” Patent Literature 1 also describes that, with the above-mentioned structure, “When the etching mask film comprising the chromium compound is patterned, the tantalum compound forming the surface-reflection preventing layer has higher resistance against an oxygen-containing chlorine-based gas as an etching gas, as compared with the transition metal silicide. Therefore, it is possible to perform over-etching so that a side wall of a processed cross-section of the etching mask film upstands substantially vertically.”

### PRIOR ART LITERATURE

### Patent Literature

Patent Literature 1: JP 5606028 B2

### SUMMARY OF THE DISCLOSURE

### Problem to be Solved by the Disclosure

However, the chromium compound constituting the hard mask film (etching mask film) is etched isotropically with respect to the oxygen-containing chlorine-based gas. Therefore, when the hard mask film (etching mask film) composed of the chromium compound is patterned in etching using a resist film as a mask, it is inevitable that an etched side wall (side wall of the processed cross-section) recedes and an opening width (opening size) of a pattern formed on the hard mask film increases. This could be a factor of inhibiting miniaturization of a pattern formed on a pattern-forming thin film by etching using the patterned hard mask film as a mask. Furthermore, this could also be a factor of preventing high integration of a semiconductor device manufactured using a transfer mask having the pattern-forming thin film.

In view of the above, it is an aspect of the present disclosure to provide a mask blank capable of forming a fine pattern on a pattern-forming thin film, and a method for manufacturing a transfer mask.

It is another aspect of the present disclosure to provide a method for manufacturing a semiconductor device, using a transfer mask manufactured by the above-mentioned transfer mask manufacturing method.

### Means for Solving the Problem

The present disclosure has the following configurations as means for solving the above-mentioned problem.

### Configuration 1

A mask blank having a structure in which a pattern-forming thin film, a first hard mask film, and a second hard mask film are stacked on a main surface of a substrate in this order,
wherein the pattern-forming thin film contains at least one element selected from silicon and transition metals,
wherein the first hard mask film contains chromium,
wherein the second hard mask film contains tantalum,
wherein tantalum in the second hard mask film includes tantalum which is unsaturated with oxygen,
wherein the pattern-forming thin film has a film thickness of 20 nm or more,
wherein the first hard mask film has a film thickness of 15 nm or less, and
wherein the second hard mask film has a film thickness of 10 nm or less.

### Configuration 2

A mask blank having a structure in which a pattern-forming thin film, a first hard mask film, and a second hard mask film are stacked on a main surface of a substrate in this order,
wherein the pattern-forming thin film contains at least one element selected from silicon and transition metals,
wherein the first hard mask film contains chromium,
wherein the second hard mask film contains tantalum and swells in an oxygen-containing gas atmosphere,
wherein the pattern-forming thin film has a film thickness of 20 nm or more,
wherein the first hard mask film has a film thickness of 15 nm or less, and
wherein the second hard mask film has a film thickness of 10 nm or less.

### Configuration 3

The mask blank according to Configuration 1 or 2,
wherein a ratio of an oxygen content to a tantalum content in the second hard mask film is 1.5 or less.

### Configuration 4

The mask blank according to any one of Configurations 1 to 3,
wherein the second hard mask film contains a greatest amount of tantalum among metal elements and silicon.

### Configuration 5

The mask blank according to any one of Configurations 1 to 4,
wherein the second hard mask film has a film thickness of 1 nm or more.

### Configuration 6

The mask blank according to any one of Configurations 1 to 5,
wherein the first hard mask film contains chromium and at least one of oxygen and nitrogen.

### Configuration 7

The mask blank according to any one of Configurations 1 to 6,
wherein the first hard mask film has a film thickness greater than a thickness of the second hard mask film.

### Configuration 8

The mask blank according to any one of Configurations 1 to 7,
wherein the pattern-forming thin film is a light-absorbing film containing tantalum, and
wherein the mask blank has a multilayer reflective film between the substrate and the pattern-forming thin film.

### Configuration 9

The mask blank according to any one of Configurations 1 to 8,
wherein the pattern-forming thin film is a light-shielding film containing silicon.

### Configuration 10

A method for manufacturing a transfer mask using the mask blank according to any one of Configurations 1 to 9, the method comprising:
forming a second hard mask pattern in the second hard mask film by dry etching using a resist film, as a mask, formed on the second hard mask film and having a pattern,
forming a first hard mask pattern in the first hard mask film, concurrently swelling an etched side wall of the second hard mask pattern, by dry etching using an oxygen-containing gas with the second hard mask pattern used as a mask; and
forming a thin film pattern in the pattern-forming thin film by dry etching with the first hard mask pattern used as a mask.

### Configuration 11

A method for manufacturing a semiconductor device, comprising:
an exposure step of using the transfer mask manufactured by the transfer mask manufacturing method according to Configuration 10 and transferring, by lithography, the thin film pattern of the transfer mask to a resist film on a substrate for a semiconductor device.

### Effect of the Disclosure

According to the present disclosure, it is possible to provide a mask blank capable of forming a fine pattern on a pattern-forming thin film, a method for manufacturing a transfer mask, and a method for manufacturing a semiconductor device using a transfer mask manufactured by the transfer mask manufacturing method.

### BRIEF DESCRIPTION OF THE DRAWINGS

FIG. 1 is a cross-sectional view showing a structure of a mask blank according to a first embodiment of the present disclosure;

FIG. 2A is a manufacturing process diagram (part 1) showing a transfer mask manufacturing method using the mask blank according to the first embodiment of the present disclosure;

FIG. 2B is a manufacturing process diagram (part 1), following FIG. 2A, showing the transfer mask manufacturing method;

FIG. 2C is a manufacturing process diagram (part 1), following FIG. 2B, showing the transfer mask manufacturing method;

FIG. 3A is a manufacturing process diagram (part 2) showing the transfer mask manufacturing method using the mask blank according to the first embodiment of the present disclosure;

FIG. 3B is a manufacturing process diagram (part 2), following FIG. 3A, showing the transfer mask manufacturing method;

FIG. 4 is a cross-sectional view showing a structure of a mask blank according to a second embodiment of the present disclosure;

FIG. 5A is a manufacturing process diagram (part 1) showing a transfer mask manufacturing method using the mask blank according to the second embodiment of the present disclosure;

FIG. 5B is a manufacturing process diagram (part 1), following FIG. 5A, showing the transfer mask manufacturing method;

FIG. 5C is a manufacturing process diagram (part 1), following FIG. 5B, showing the transfer mask manufacturing method;

FIG. 6A is a manufacturing process diagram (part 2) showing the transfer mask manufacturing method using the mask blank according to the second embodiment of the present disclosure;

FIG. 6B is a manufacturing process diagram (part 2), following FIG. 6A, showing the transfer mask manufacturing method;

FIG. 7 is a diagram for describing examples of the present disclosure and comparative examples;

FIG. 8A is a manufacturing process diagram showing a transfer mask manufacturing method of the comparative examples;

FIG. 8B is a manufacturing process diagram, following FIG. 8A, showing the transfer mask manufacturing method of the comparative examples;

FIG. 8C is a manufacturing process diagram, following FIG. 8B, showing the transfer mask manufacturing method of the comparative examples; and

FIG. 8D is a manufacturing process diagram, following FIG. 8C, showing the transfer mask manufacturing method of the comparative examples.

### MODE FOR EMBODYING THE DISCLOSURE

Now, embodiments to which the present disclosure is applied will be described with reference to the drawings. Description will be made using the same reference numerals assigned to similar components in the figures.

### First Embodiment

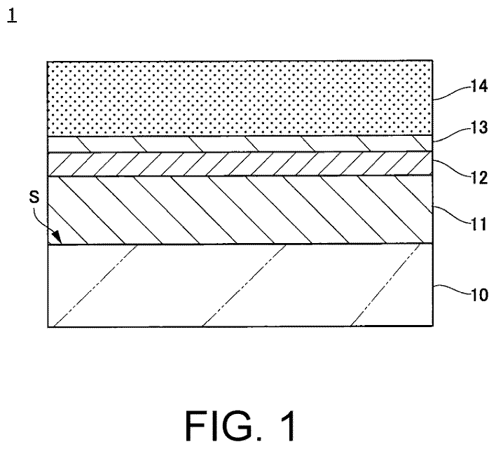

First, a structure of a mask blank 1 according to a first embodiment of the present disclosure will be described with reference to FIG. 1. Next, a method for manufacturing a transfer mask using the mask blank 1 and a method for manufacturing a semiconductor device will be described.

### <Mask Blank 1>

FIG. 1 is a cross-sectional view showing the structure of the mask blank 1 according to the first embodiment of the present disclosure. The mask blank 1 shown in FIG. 1 is used in manufacture of a transmissive transfer mask. The mask blank 1 has a structure in which, on one main surface S of a transparent substrate 10, a pattern-forming thin film 11, a first hard mask film 12, and a second hard mask film 13 are stacked in this order from a side adjacent to the transparent substrate 10. The mask blank 1 may have a structure in which a resist film 14 is stacked on the second hard mask film 13 as necessary. In the following, details of the main components of the mask blank 1 will be described.

### [Transparent Substrate 10]

The transparent substrate 10 as a substrate in the first embodiment is made of a material excellent in transmittivity to exposure light used in an exposure process in lithography. In a case where ArF excimer laser light (wavelength: 193 nm) is used as the exposure light, the substrate may be made of a material having transmittivity thereto. As such a material, synthetic quartz glass is used. In addition, it is possible to use aluminosilicate glass, soda lime glass, low-thermal-expansion glass (SiO₂—TiO₂ glass, etc.), and various other glass substrates. In particular, a quartz substrate is highly transparent in a region of the ArF excimer laser light or a shorter wavelength region and, therefore, can be used particularly suitably for the mask blank of the present disclosure.

The exposure process in lithography referred to herein is an exposure process in lithography using a transmissive transfer mask manufactured using the mask blank 1. In the following, the exposure light is supposed to be exposure light used in the exposure process mentioned above. As the exposure light, any of the ArF excimer laser light (wavelength: 193 nm), KrF excimer laser light (wavelength: 248 nm), and i-line light (wavelength: 365 nm) is applicable. However, in view of pattern miniaturization in the exposure process, it is desirable to apply the ArF excimer laser light as the exposure light. Therefore, an embodiment with respect to a case where the ArF excimer laser light is used as the exposure light will be described in the following.

### [Pattern-Forming Thin Film 11]

The pattern-forming thin film 11 is a light-shielding film for the exposure light. Such a pattern-forming thin film 11 may contain at least one element selected from silicon and transition metals. By way of example here, the pattern-forming thin film 11 is formed of a material containing silicon (Si). The pattern-forming thin film 11 is preferably formed of a material containing nitrogen (N) in addition to silicon. Such a pattern-forming thin film 11 can be patterned by dry etching using a fluorine-based gas, and can be patterned with sufficient etching selectivity with respect to the first hard mask film 12 of a material containing chromium (Cr), which will be described below.

Furthermore, the pattern-forming thin film 11 may contain one or more elements selected from metalloid elements, non-metal elements, and metal elements when patterning is possible by the dry etching using the fluorine-based gas.

Among those elements, the metalloid elements may be any metalloid element in addition to silicon and include, for example, boron (B), germanium (Ge), antimony (Sb), and tellurium (Te). The non-metal elements may be any non-metal element (including halogen and a noble gas) in addition to nitrogen (N) and include, for example, one or more elements selected from oxygen (O), carbon (C), hydrogen (H), phosphorus (P), sulfur(S), selenium (Se), fluorine (F), helium (He), argon (Ar), krypton (Kr), and xenon (Xe). Metal elements are exemplified by molybdenum (Mo), tungsten (W), titanium (Ti), tantalum (Ta), zirconium (Zr), hafnium (Hf), niobium (Nb), vanadium (V), cobalt (Co), chromium (Cr), nickel (Ni), ruthenium (Ru), and tin (Sn).

A film thickness of the pattern-forming thin film 11 is not particularly limited but may be, for example, 20 nm or more in order to obtain a sufficient light-shielding property for the exposure light. Thus, when the pattern-forming thin film 11 is etched, a second hard mask pattern 13P (which will later be described) can efficiently be removed while ensuring the light-shielding property of the pattern-forming thin film 11. In order to form a fine pattern with high accuracy, the film thickness of the pattern-forming thin film 11 is preferably 70 nm or less, more preferably 60 nm or less, further preferably 50 nm or less.

### [First Hard Mask Film 12]

The first hard mask film 12 is preferably composed of a material having sufficient etching resistance in the dry etching of the pattern-forming thin film 11 using the fluorine-based gas. Such a first hard mask film 12 may be composed of a material containing, for example, chromium (Cr). The first hard mask film 12 of the material containing chromium (Cr) can be patterned by dry etching using an oxygen-containing gas. The chromium-containing material constituting the first hard mask film 12 includes chromium metal and a material containing chromium and at least one of oxygen, nitrogen, and carbon. In particular, the first hard mask film 12 preferably contains chromium and at least one of oxygen and nitrogen, and may contain, for example, chromium and nitrogen. Thus, it is possible to increase an etching rate in a case where the first hard mask film 12 is etched by using the oxygen-containing gas as an etchant.

The first hard mask film 12 has sufficient etching selectivity with respect to the pattern-forming thin film 11 of the material containing silicon (Si). Therefore, it is possible to etch and remove the first hard mask film 12 with little or no damage given to the pattern-forming thin film 11.

Furthermore, the first hard mask film 12 has sufficient etching selectivity with respect to the second hard mask film 13 of a material containing tantalum (Ta), which will later be described. Therefore, the first hard mask film 12 can be patterned using the second hard mask film 13 as a mask.

The first hard mask film 12 described above may have a film thickness of, for example, 15 nm or less for formation of a fine pattern. The film thickness of the first hard mask film 12 is preferably greater than the film thickness of the second hard mask film 13 which will be described in the following.

### [Second Hard Mask Film 13]

The second hard mask film 13 is preferably composed of a material which has sufficient etching resistance and swells in the dry etching of the first hard mask film 12 using the oxygen-containing gas. Such a second hard mask film 13 may be composed of a material containing tantalum (Ta). That is, it is sufficient when the material of the second hard mask film 13 contains tantalum (Ta) and swells in an oxygen-containing gas atmosphere. The tantalum (Ta)-containing material in the second hard mask film 13 contains tantalum (Ta) unsaturated with oxygen. It may be said that the material constituting the second hard mask film 13 contains tantalum (Ta) which is incompletely oxidized. Since completely oxidized tantalum (Ta) becomes tantalum pentoxide (Ta₂O₅) which is stable, it may be said that incompletely oxidized tantalum (Ta) means tantalum in a bonding state other than Ta₂O₅ bond.

Thus, in the dry etching of the first hard mask film 12 using the oxygen-containing gas, tantalum (Ta) contained in the second hard mask film 13 is oxidized and the second hard mask film 13 swells. A ratio of an oxygen content to a tantalum (Ta) content in the second hard mask film 13 is preferably 1.5 or less. This makes a swelling amount due to oxidation of tantalum (Ta) have a sufficient value. The swelling amount can be controlled by appropriately adjusting the ratio of the oxygen content to the tantalum (Ta) content in the second hard mask film 13. More specifically, by controlling film-forming conditions (a composition ratio of atoms constituting a sputtering target, a type of a sputtering gas, a gas flow rate ratio, etc.) when the second hard mask film 13 is formed, the ratio of the oxygen content to the tantalum (Ta) content in the second hard mask film 13 may be adjusted to a desired value. It is noted here that a film-forming apparatus inevitably has inherent characteristics and, therefore, the film-forming conditions should be adjusted in conformity with each individual film-forming apparatus to be used. The contents of tantalum (Ta) and oxygen (O) can be measured by XPS (X-ray photoelectron spectroscopy).

The second hard mask film 13 may contain, in addition to tantalum (Ta), at least one of silicon and another metal element other than tantalum (Ta). When the second hard mask film 13 contains at least one of silicon and another metal element other than tantalum (Ta), the second hard mask film 13 preferably contains a greatest amount of tantalum (Ta) among tantalum (Ta), another metal element, and silicon. It may be said that the second hard mask film 13 preferably contains a greatest amount of tantalum, except for oxygen. This makes the swelling amount due to oxidation of tantalum (Ta) have a sufficient value.

The second hard mask film 13 has a film thickness which is preferably smaller than the film thickness of the first hard mask film 12. The film thickness of the second hard mask film 13 is, for example, 10 nm or less. By setting a smaller film thickness of the second hard mask film 13, it is possible to reduce a film thickness of the resist film 14 as an etching mask for the second hard mask film 13 and to miniaturize a pattern formed on the pattern-forming thin film 11. Furthermore, by making the film thickness of the second hard mask film 13 smaller than the film thickness of the first hard mask film 12, the second hard mask film 13 can be removed while leaving the first hard mask film 12 remaining when the pattern-forming thin film 11 is etched using the first hard mask film 12 as a mask, as will later be described. The film thickness of the second hard mask film 13 is 1 nm or more. Thus, it is possible to obtain an effect that, in the dry etching of the first hard mask film 12 using the oxygen-containing gas, an etched side wall of the second hard mask film 13 (second hard mask pattern 13P), which has already been patterned, swells in a sufficient size. The etched side wall of the second hard mask pattern 13P means a side wall of the second hard mask pattern when the mask blank 1 with the second hard mask film 13 patterned is seen in a cross-sectional view. In the cross-sectional view, an angle formed between the sidewall and a main surface of the substrate is a right angle or a substantially right angle.

### [Resist Film 14]

In the mask blank 1, the resist film 14 is preferably formed in contact with a surface of the second hard mask film 13. The resist film 14 is, for example, a chemically amplified positive resist, but is not limited thereto as long as a fine pattern can be formed. More preferably, the resist film 14 has a film thickness of 80 nm or less, for example, from the viewpoint of forming a fine pattern by lithography processing of the resist film 14 and from the viewpoint of preventing pattern collapse of a formed resist pattern.

### <Method for Manufacturing Transfer Mask>

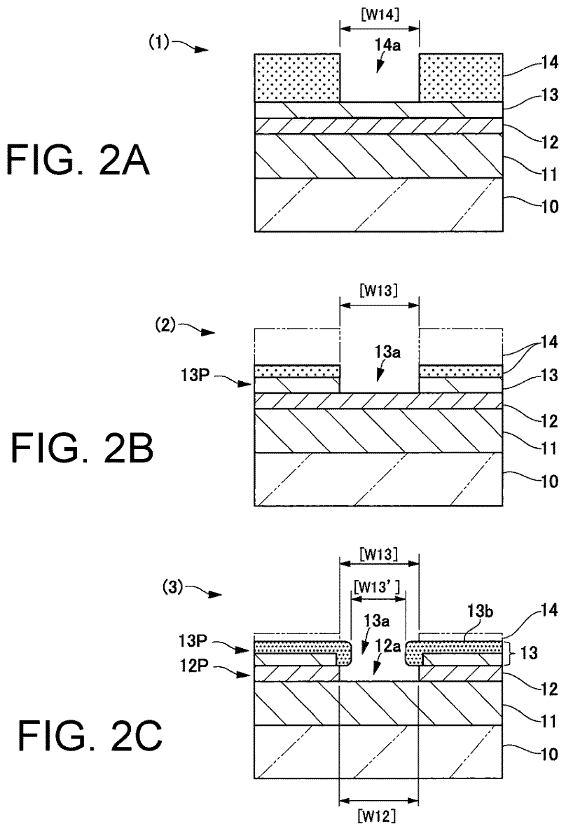

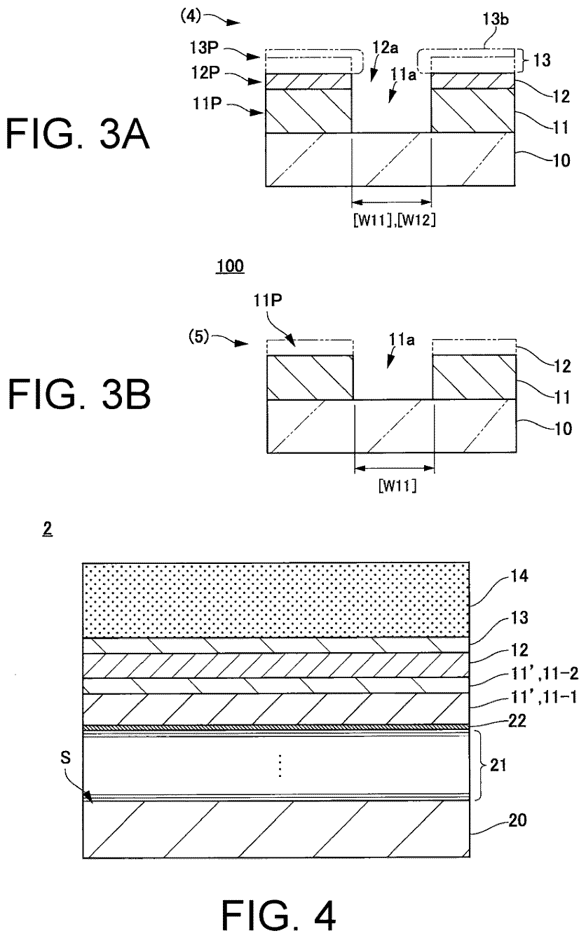

FIGS. 2A-2C are manufacturing process diagrams (part 1) showing a transfer mask manufacturing method using the mask blank 1 of the first embodiment of the present disclosure. FIGS. 3A and 3B are manufacturing process diagrams (part 2) showing the transfer mask manufacturing method using the mask blank 1 of the first embodiment of the present disclosure. Now, the method for manufacturing a transmissive transfer mask will be described with reference to these figures.

First, the mask blank 1 having the structure described with reference to FIG. 1 is prepared. When the mask blank 1 does not have the resist film 14, the resist film 14 is formed on the second hard mask film 13. As shown in FIG. 1, the mask blank 1 may be provided with the resist film 14. In this case, a film-forming step of the resist film 14 is not required.

### Step (1)

In a step (1) shown in FIG. 2A, a pattern to be formed on the pattern-forming thin film 11 is drawn by exposure on the resist film 14 of the mask blank 1. For drawing by exposure, an electron beam may be used. Thereafter, as necessary, the resist film 14 is subjected to predetermined processing, such as PEB (Post Exposure Bake), development, and post baking, to pattern the resist film 14. The patterned resist film 14 has a space pattern 14a, and an opening width [W14] of the space pattern 14a is, for example, a minimum space width. It is noted here that the space pattern in the first embodiment refers to a pattern formed by partially removing the film, and includes a linear pattern and a hole-shaped pattern (hole pattern). The space pattern may also be referred to as a blank pattern. When the space pattern has a hole shape, the opening width [W14] is a hole diameter. This also applies in the following description.

### Step (2)

In a step (2) shown in FIG. 2B, the second hard mask film 13 is etched using the patterned resist film 14 as a mask. At this time, the second hard mask film 13 of the tantalum (Ta)-containing material is patterned by dry etching using a fluorine-based gas as an etchant to transfer the pattern formed on the resist film 14 to the second hard mask film 13. Thus, the second hard mask pattern 13P is formed on the second hard mask film 13.

Here, the dry etching of the tantalum (Ta)-containing material using the fluorine-based gas as the etchant is highly anisotropic. Therefore, the second hard mask pattern 13P is provided with a space pattern 13a having an opening width [W13] substantially equal to the opening width [W14] of the space pattern 14a formed in the resist film 14. In this step, the resist film 14 may remain on the second hard mask pattern 13P. The remaining resist film 14 may be removed by ashing using oxygen gas or ozone gas, or may be removed during etching of the first hard mask film 12, as will later be described.

### Step (3)

In a step (3) shown in FIG. 2C, the first hard mask film 12 is etched using the second hard mask pattern 13P as a mask. At this time, the oxygen-containing gas is used as an etchant also in order to swell the second hard mask pattern 13P. By the dry etching, the first hard mask film 12 is patterned to form a first hard mask pattern 12P. When the first hard mask film 12 is composed of the chromium (Cr)-containing material, it is preferable that the gas as the etchant further contains chlorine gas in addition to oxygen. It is noted here that the resist film 14 left on the second hard mask pattern 13P may be ashed and removed by an oxygen-containing etchant.

In the dry etching, the gas containing oxygen and chlorine is used as the etchant. The etching of the first hard mask film 12 of the chromium (Cr)-containing material proceeds slightly isotropically, although not to the extent in wet etching.

Here, in this dry etching, the second hard mask pattern 13P is exposed to the oxygen-containing gas, and tantalum (Ta) contained in the second hard mask pattern 13P is oxidized. This oxidation spreads isotropically from an exposed surface of the second hard mask pattern 13P, and the exposed surface of the second hard mask pattern 13P is constituted by an oxidized part 13b. By swelling due to the oxidation, the opening width [W13] of the space pattern 13a formed in the second hard mask pattern 13P becomes an opening width [W13′] which has been reduced by the swelling of the second hard mask pattern 13P. When the remaining resist film 14 is removed by ashing using the oxygen gas or the ozone gas as described above, tantalum (Ta) contained in the second hard mask pattern 13P is oxidized and the second hard mask pattern 13P swells in this ashing step also. This applies also to a second embodiment which will later be described.

Therefore, the isotropic dry etching of the first hard mask film 12 proceeds using the second hard mask pattern 13P, as a mask, having the opening width [W13′] smaller than the opening width [W14] of the space pattern 14a formed in the resist film 14 in the step (1). Thus, the first hard mask film 12 is provided with the first hard mask pattern 12P having a space pattern 12a of a small opening width [W12] with side etching suppressed by an amount corresponding to the swelling amount of the second hard mask pattern 13P.

### Step (4)

In a step (4) shown in FIG. 3A, the pattern-forming thin film 11 is etched using the first hard mask pattern 12P as a mask. At this time, the pattern-forming thin film 11 composed of the silicon (Si)-containing material is patterned by dry etching using a fluorine-based gas as an etchant to form a thin film pattern 11P obtained by transferring the first hard mask pattern 12P to the pattern-forming thin film 11. While the pattern-forming thin film 11 is etched, the second hard mask pattern 13P left on the first hard mask pattern 12P, including the oxidized part 13b, is preferably etched and removed by the fluorine-based gas as the etchant.

The dry etching of the silicon (Si)-containing material using the fluorine-based gas as the etchant is highly anisotropic. Therefore, a space pattern 11a having an opening width [W11], which is substantially as small as the opening width [W12] of the space pattern 12a formed in the first hard mask pattern 12P, is formed in the thin film pattern 11P of the silicon (Si)-containing material.

### Step (5)

In a step (5) shown in FIG. 3B, the first hard mask pattern 12P on the thin film pattern 11P is etched and removed. At this time, the first hard mask pattern 12P of the chromium (Cr)-containing material is etched by dry etching using a chlorine-containing gas as an etchant. The chlorine-containing gas may further contain oxygen.

Thus, a transmissive transfer mask 100 is obtained in which the thin film pattern 11P formed by patterning the pattern-forming thin film 11 is provided on the transparent substrate 10 as a light-shielding pattern. The thin film pattern 11P formed in the transfer mask 100 has the space pattern 11a having the small opening width [W11] with side etching suppressed by the amount corresponding to the swelling amount of the second hard mask pattern 13P.

In the manner mentioned above, the transfer mask 100 having the thin film pattern 11P provided with the finer space pattern 11a is obtained.

### <Method for Manufacturing Semiconductor Device>

The semiconductor device manufacturing method is characterized by using the transmissive transfer mask 100 manufactured by the transfer mask manufacturing method described above and performing transfer by exposure of the thin film pattern 11P to a resist film on a substrate for a semiconductor device. The semiconductor device manufacturing method is executed as follows.

First, a substrate to be provided with a semiconductor device is prepared. The substrate may be, for example, a semiconductor substrate, a substrate having a semiconductor thin film, or those substrates with a microfabricated film formed thereon. A resist film is formed on the prepared substrate. The resist film is subjected to pattern exposure using the transfer mask 100 to transfer the thin film pattern 11P formed in the transfer mask 100 to the resist film. At this time, any of the ArF excimer laser light (wavelength: 193 nm), the KrF excimer laser light (wavelength: 248 nm), and the i-line light (wavelength: 365 nm) is applicable as the exposure light as described above. In view of pattern miniaturization, however, it is desirable to use the ArF excimer laser light as the exposure light.

Thereafter, the resist film to which the thin film pattern 11P is transferred by exposure is developed to form a resist pattern. Using the resist pattern as a mask, a surface layer of the substrate is subjected to etching and introduction of impurities. After completion of those processes, the resist pattern is removed.

Such lithography process is repeatedly performed on the substrate while changing the transfer mask 100 and further processes as required are performed to complete the semiconductor device.

In the above-mentioned manufacture of the semiconductor device, a highly-integrated semiconductor device can be obtained by using the transfer mask 100 having the fine space pattern 11a, which is manufactured by the transfer mask manufacturing method described above.

### Second Embodiment

First, a structure of a mask blank 2 according to the second embodiment will be described with reference to FIG. 4. Next, a method for manufacturing a transfer mask using the mask blank 2 and a method for manufacturing a semiconductor device will be described.

### <Mask Blank 2>

FIG. 4 is a cross-sectional view showing the structure of the mask blank 2 according to the second embodiment of the present disclosure. The mask blank 2 shown in the figure is an original plate of a reflective transfer mask (hereinafter will be referred to as a reflective mask) for EUV lithography using extreme ultraviolet (EUV) as exposure light. The mask blank 2 has a structure in which a multilayer reflective film 21, a protective film 22, a pattern-forming thin film 11′, the first hard mask film 12, and the second hard mask film 13 are stacked on one main surface S of a substrate 20 in this order from a side adjacent to the substrate 20. Alternatively, the mask blank 2 may have a structure in which the resist film 14 is stacked on the second hard mask film 13 as necessary. In the following, details of the main components of the mask blank 2 will be described.

### [Substrate 20]

As the substrate 20, a low-expansion glass is preferably used in order to prevent distortion of a transfer pattern due to heat generation during exposure (EUV exposure) using a reflective mask formed by processing the mask blank 2. As the low-expansion glass, for example, SiO₂—TiO₂-based glass, multi-component glass ceramics, or the like may be used. The transfer pattern is a pattern formed by processing the pattern-forming thin film 11′ which will later be described.

### [Multilayer Reflective Film 21]

The multilayer reflective film 21 is a film disposed on the main surface S of the substrate 20 between the substrate 20 and the pattern-forming thin film 11′, and reflects the EUV light as the exposure light at a high reflectance. The multilayer reflective film 21 provides a function of reflecting the EUV light to the reflective transfer mask formed using the mask blank 2, and is a multilayer film obtained by periodically stacking layers which mainly contain respective elements different in refractive index.

In general, a multilayer film in which thin films (high refractive index layers) of a light element as a high refractive index material or a compound thereof, and thin films (low refractive index layers) of a heavy element as a low refractive index material or a compound thereof, are alternately stacked in about 40 to 60 periods is used as the multilayer reflective film 21. For example, as the multilayer reflective film 21 for EUV light having a wavelength of 13 nm to 14 nm, a Mo/Si periodically stacked film comprising Mo films and Si films alternately stacked in about 40 to 60 periods is preferably used. The high refractive index layer, which is an uppermost layer of the multilayer reflective film 21, may be formed of silicon (Si).

### [Protective Film 22]

The protective film 22 is a film provided to protect the multilayer reflective film 21 from etching and cleaning when the mask blank 2 is processed to manufacture the reflective mask for EUV lithography. The protective film 22 is provided above the multilayer reflective film 21 in contact with the multilayer reflective film 21 or via another film, and may have a single layer structure or a stacked structure.

Such a protective film 22 preferably contains ruthenium (Ru). A material of the protective film 22 may be Ru elemental metal or a Ru alloy containing ruthenium (Ru) and at least one metal selected from titanium (Ti), niobium (Nb), molybdenum (Mo), zirconium (Zr), yttrium (Y), rhodium (Rh), boron (B), lanthanum (La), cobalt (Co), and rhenium (Re), and may contain nitrogen. On the other hand, for the protective film 22, a material selected from silicon-based materials such as silicon (Si), a material containing silicon (Si) and oxygen (O), a material containing silicon (Si) and nitrogen (N), or a material containing silicon (Si), oxygen (O), and nitrogen (N) may be used.

[Pattern-Forming Thin film 11′]

The pattern-forming thin film 11′ is a light absorbing film for the exposure light. Such a pattern-forming thin film 11′ may be composed of a material containing tantalum (Ta). The pattern-forming thin film 11′ may have a single layer structure, but may have a stacked structure illustrated in the figure. The stacked structure is exemplified by a stacked structure of a first thin film 11-1 and a second thin film 11-2 stacked in this order from a side adjacent to the substrate 20. Although the material of the pattern-forming thin film 11′ is not particularly limited, materials of the first thin film 11-1 and the second thin film 11-2 may be, for example, the following materials.

The first thin film 11-1 is composed of a material which is excellent in light absorption for the exposure light and which is etchable with high selectivity with respect to the protective film 22. The first thin film 11-1 is composed of, for example, a material containing at least tantalum (Ta) and nitrogen (N). In the mask blank for the reflective transfer mask, a crystalline state of a light-absorbing film preferably has an amorphous or a microcrystalline structure in view of smoothness and flatness. By adding boron (B), silicon (Si) and/or germanium (Ge) to tantalum (Ta), the amorphous structure can easily be obtained to improve the smoothness. Furthermore, addition of nitrogen (N) and/or oxygen (O) to tantalum (Ta) improves resistance to oxidation, thereby improving stability over time. From the above, the first thin film 11-1 may be, for example, TaN, TaON, TaBN, TaBON, TaCN, TaCON, TaBCN, or TaBOCN.

The second thin film 11-2 is preferably composed of a material which is excellent in light absorption for the exposure light and which is etchable with high selectivity with respect to the first hard mask film 12. The second thin film 11-2 may be composed of a material containing at least tantalum (Ta) and oxygen (O) and may be, for example, TaBO in view of smoothness and flatness. This enables patterning with sufficient etching selectivity with respect to the first hard mask film 12 of the chromium (Cr)-containing material which will be described below.

The first thin film 11-1 can be dry-etched using a fluorine-based gas or a substantially oxygen-free chlorine-based gas. The second thin film 11-2 can be dry-etched using the fluorine-based gas or the substantially oxygen-free chlorine-based gas, but is preferably etched with the fluorine-based gas, which has a higher etching rate.

The pattern-forming thin film 11′ has a film thickness of, for example, 20 nm or more in order to achieve sufficient absorption for the exposure light (EUV light). Furthermore, in order to reduce a shadowing effect, the film thickness of the pattern-forming thin film 11′ is preferably 70 nm or less, more preferably 60 nm or less, further preferably 50 nm or less.

### [First Hard Mask Film 12]

The first hard mask film 12 is the same as the first hard mask film 12 of the mask blank 1 described in the first embodiment with reference to FIG. 1. That is, the first hard mask film 12 is preferably composed of a material having sufficient etching resistance in dry etching of the pattern-forming thin film 11′ using the fluorine-based gas. Such a first hard mask film 12 may be composed of a material containing chromium (Cr) and may have, for example, a structure containing chromium and at least one of oxygen, nitrogen, and carbon. For a more detailed structure of the first hard mask film 12, description overlapping with the description of the first embodiment is omitted.

### [Second Hard Mask Film 13]

The second hard mask film 13 is the same as the second hard mask film 13 of the mask blank 1 described in the first embodiment with reference to FIG. 1. That is, the second hard mask film 13 is composed of a material which has sufficient etching resistance and swells in dry etching of the first hard mask film 12 using the oxygen-containing gas. Such a second hard mask film 13 is preferably composed of a material containing tantalum (Ta). For a more detailed structure of the second hard mask film 13, description overlapping with the description of the first embodiment is omitted.

### [Resist Film 14]

The resist film 14 is the same as the resist film 14 of the mask blank 1 described in the first embodiment with reference to FIG. 1. Herein, for a detailed structure, description overlapping with the description of the first embodiment is omitted.

### <Method for Manufacturing Transfer Mask>

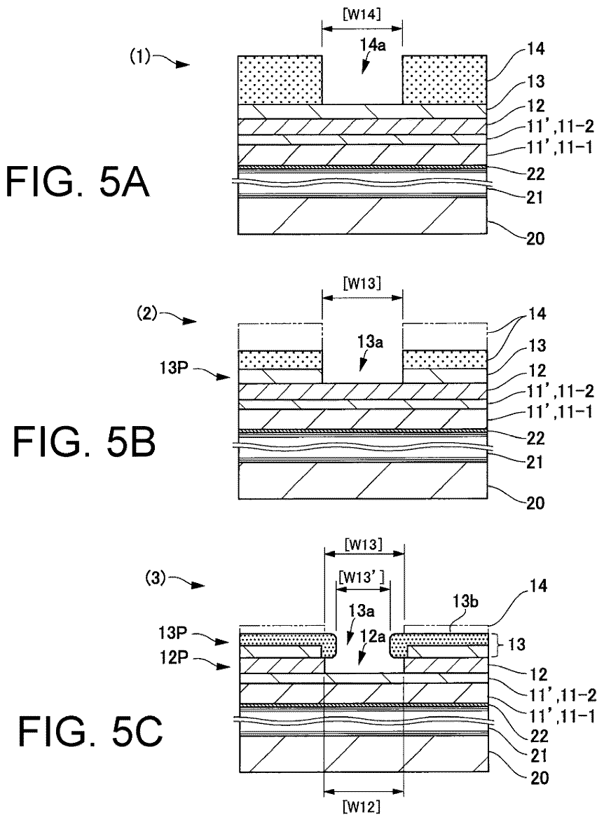

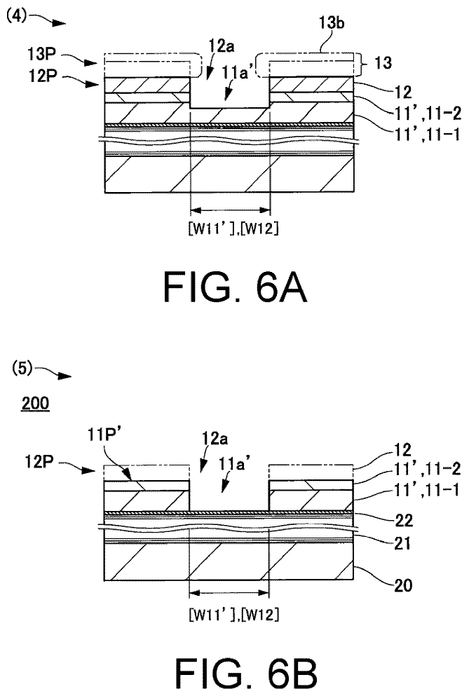

FIGS. 5A-5C are manufacturing process diagrams (part 1) showing a transfer mask manufacturing method using the mask blank 2 of the second embodiment of the present disclosure. FIGS. 6A and 6B are manufacturing process diagrams (part 2) showing the transfer mask manufacturing method using the mask blank 2 of the second embodiment of the present disclosure. The procedure of the manufacturing method shown in these figures is basically the same as that of the manufacturing method described in the first embodiment with reference to FIGS. 2A-2C, 3A, and 3B. Hereinafter, the method for manufacturing the reflective transfer mask will be described with reference to these figures.

First, the mask blank 2 having the structure described with reference to FIG. 4 is prepared. When the mask blank 2 does not have the resist film 14, the resist film 14 is formed on the second hard mask film 13. As shown in FIG. 4, the mask blank 2 may be provided with the resist film 14. In this case, the film-forming step of the resist film 14 is not required.

### Steps (1)-(3)

Next, steps (1) to (3) shown in FIGS. 5A-5C are performed by the same procedure as the steps (1) to (3) shown in FIGS. 2A-2C in the first embodiment. Therefore, detailed description is omitted here.

In particular, in the step (3), the first hard mask film 12 containing chromium (Cr) is patterned by isotropic dry etching using an oxygen-containing gas with the second hard mask pattern 13P as a mask. In this dry etching, it is preferable to use a gas containing chlorine in addition to oxygen.

In this dry etching, the second hard mask pattern 13P is exposed to the oxygen-containing gas, and tantalum (Ta) contained in the second hard mask pattern 13P is oxidized. This oxidation spreads isotropically from the exposed surface of the second hard mask pattern 13P, and the exposed surface of the second hard mask pattern 13P is constituted by the oxidized part 13b. By swelling due to the oxidation, the opening width [W13] of the space pattern 13a formed in the second hard mask pattern 13P becomes the opening width [W13′] which has been reduced by the swelling of the second hard mask pattern 13P.

Therefore, the isotropic dry etching of the first hard mask film 12 proceeds using the second hard mask pattern 13P, as a mask, having the opening width [W13′] smaller than the opening width [W14] of the space pattern 14a formed in the resist film 14 in the step (1) of FIG. 5A. Thus, the first hard mask film 12 is provided with the first hard mask pattern 12P having the space pattern 12a of the small opening width [W12] with side etching suppressed by the amount corresponding to the swelling amount of the second hard mask pattern 13P.

### Step (4)

In a step (4) shown in FIG. 6A, the second thin film 11-2 in the pattern-forming thin film 11′ is etched using the first hard mask pattern 12P as a mask. At this time, the second thin film 11-2 composed of the material containing at least tantalum (Ta) and oxygen (O) is patterned by dry etching using a fluorine-based gas as an etchant to transfer the pattern formed in the first hard mask pattern 12P to the second thin film 11-2. While the second thin film 11-2 is etched, the second hard mask pattern 13P left on the first hard mask pattern 12P, including the oxidized part 13b, is preferably etched and removed by the fluorine-based gas as the etchant.

The dry etching of the material containing tantalum (Ta) using the fluorine-based gas as the etchant is highly anisotropic. Therefore, a space pattern 11a′ of an opening width [W11′], which is substantially as small as the opening width [W12] of the space pattern 12a formed in the first hard mask pattern 12P, is formed on the second thin film 11-2 of the material containing at least tantalum (Ta) and oxygen (O).

### Step (5)

In a step (5) shown in FIG. 6B, the first thin film 11-1 in the pattern-forming thin film 11′ is etched using the first hard mask pattern 12P as a mask. At this time, the first thin film 11-1 of the material containing at least tantalum (Ta) and nitrogen (N) is patterned by dry etching using chlorine gas as an etchant to transfer the pattern formed in the first hard mask pattern 12P to the first thin film 11-1. While the first thin film 11-1 is etched, the first hard mask pattern 12P left on the second thin film 11-2 is preferably etched and removed by the chlorine-based gas as the etchant.

The dry etching of the tantalum (Ta)-containing material using the chlorine-based gas as the etchant is highly anisotropic. Therefore, the space pattern 11a′ having the opening width [W11′], which is substantially as small as the opening width [W12] of the space pattern 12a formed in the first hard mask pattern 12P, is formed on the first thin film 11-1 of the material containing at least tantalum (Ta) and nitrogen (N).

In the dry etching using the chlorine-based gas as the etchant, the protective film 22 containing ruthenium (Ru) serves as an etching stopper to protect the multilayer reflective film 21.

Thus, a reflective transfer mask 200 is obtained in which a thin film pattern 11P′ to serve as a light-absorbing pattern is provided on the substrate 20 via the multilayer reflective film 21 and the protective film 22. The thin film pattern 11P′ formed in the transfer mask 200 has the space pattern 11a′ having the small opening width [W11′] with side etching suppressed by the amount corresponding to the swelling amount of the second hard mask pattern 13P.

In the manner mentioned above, the reflective transfer mask 200 having the thin film pattern 11P′ provided with the finer space pattern 11a′ is obtained.

### <Method for Manufacturing Semiconductor Device>

The semiconductor device manufacturing method is characterized by using the reflective transfer mask 200 manufactured by the transfer mask manufacturing method described above and performing transfer by exposure of the thin film pattern 11P′ to a resist film on a substrate for a semiconductor device. The semiconductor device manufacturing method is executed as follows.

First, a substrate to be provided with a semiconductor device is prepared. The substrate may be, for example, a semiconductor substrate, a substrate having a semiconductor thin film, or those substrates with a microfabricated film formed thereon. A resist film is formed on the prepared substrate. The resist film is subjected to pattern exposure using the transfer mask 200 to transfer the thin film pattern 11P′ formed in the transfer mask 200 to the resist film. At this time, EUV light is used as exposure light, and the resist film is irradiated with the exposure light (EUV light) reflected by the transfer mask 200.

Thereafter, the resist film to which the thin film pattern 11P′ is transferred by exposure is developed to form a resist pattern. Using the resist pattern as a mask, a surface layer of the substrate is subjected to etching and introduction of impurities. After completion of these processes, the resist pattern is removed.

Such lithography process is repeatedly performed on the substrate while changing the transfer mask 200 and further processes as required are performed to complete the semiconductor device.

In the above-mentioned manufacture of the semiconductor device, a highly-integrated semiconductor device can be obtained by using the transfer mask 200 having the fine space pattern 11a′, which is manufactured by the transfer mask manufacturing method described above.

### EXAMPLE

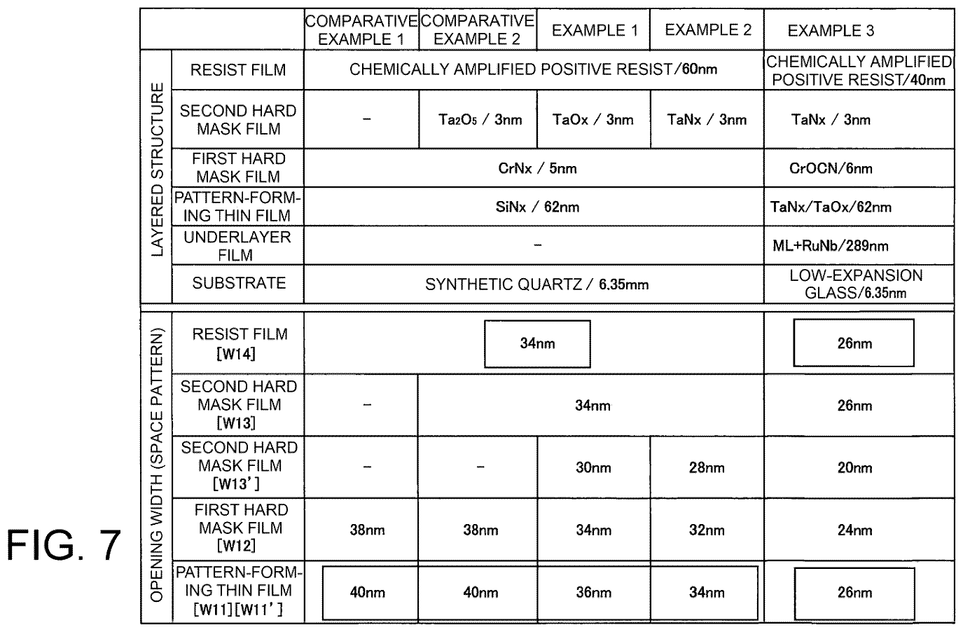

Next, Examples 1-3 to which the present disclosure is applied, and Comparative Examples 1 and 2 will be described. The results shown in these Examples and Comparative Examples were obtained by simulation based on an etching rate of each film of a mask blank for each etching gas and on a swelling rate of a tantalum-containing film (second hard mask film) under an oxygen gas atmosphere, the etching rate and the swelling rate having been previously acquired. FIG. 7 is a diagram for describing Examples and Comparative Examples. FIG. 7 illustrates structures of the mask blanks in Examples and Comparative Examples, and opening widths of space patterns formed in each film of the mask blanks. Now, Comparative Examples and Examples will be described with reference to FIGS. 1-6A, 6B, and other figures together with FIG. 7.

### Comparative Example 1

### [Preparation of Mask Blank]

As the mask blank of Comparative Example 1, a mask blank for use in manufacturing a transmissive transfer mask was prepared as follows.

First, on the transparent substrate 10 made of synthetic quartz glass and having a thickness of about 6.35 mm, silicon nitride (SiNₓ) was deposited by sputtering with a film thickness of 62 nm as the pattern-forming thin film 11. On the pattern-forming thin film 11, chromium nitride (CrNₓ) was deposited by sputtering with a film thickness of 5 nm as the first hard mask film 12. On the first hard mask film 12, a chemically amplified positive resist was deposited with a film thickness of 60 nm as the resist film 14, without forming the second hard mask film 13, to obtain the mask blank of Comparative Example 1.

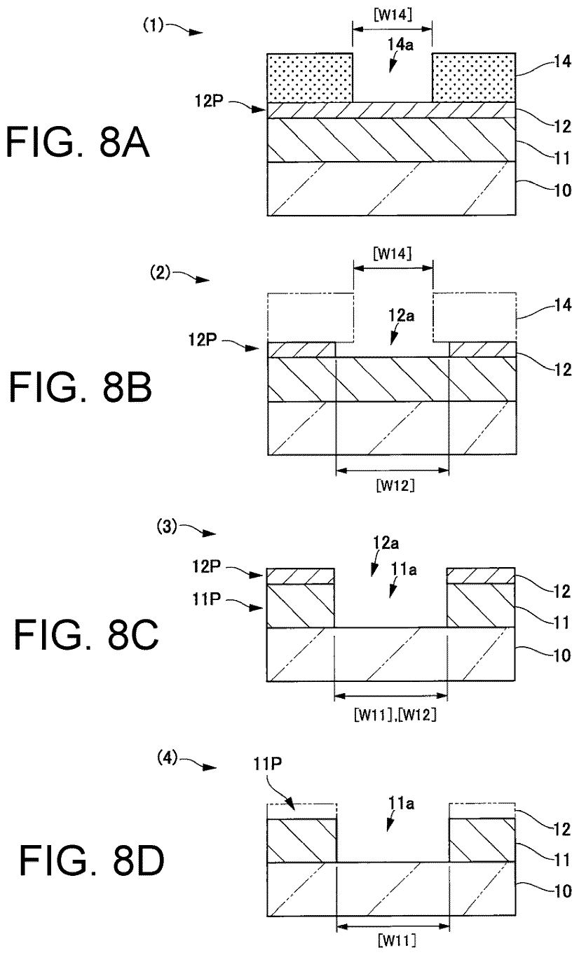

### [Preparation of Transfer Mask (see FIG. 7 and FIGS. 8A-8D)]

A transmissive transfer mask was prepared using the mask blank of Comparative Example 1. FIGS. 8A-8D are manufacturing process diagrams showing a method for manufacturing the transfer mask of Comparative Example 1. Now, referring to FIGS. 8A-8D, a procedure for preparing the transfer mask using the mask blank of Comparative Example 1 will be described.

First, as shown in a step (1) of FIG. 8A, the space pattern 14a having the opening width [W14]=34 nm was formed in the resist film 14 by lithography. The opening width [W14] is the minimum space width achieved by lithography for manufacture of the transmissive transfer mask at present.

Next, as shown in a step (2) of FIG. 8B, the first hard mask film 12 was etched using the patterned resist film 14 as a mask. At this time, the first hard mask film 12 of chromium nitride (CrNₓ) was patterned by dry etching using oxygen-containing chlorine gas (Cl₂+O₂) as an etchant to form the first hard mask pattern 12P having the space pattern 12a. In this etching, the first hard mask film 12 of chromium nitride (CrNₓ) was isotropically etched. Therefore, the opening width [W12] of the space pattern 12a formed in the first hard mask pattern 12P is greater than the opening width [W14] of the resist film 14, and the opening width [W12]=38 nm. The resist film 14 left on the first hard mask pattern 12P was ashed and removed by the oxygen-containing etchant.

Next, as shown in a step (3) of FIG. 8C, the pattern-forming thin film 11 was etched using the first hard mask pattern 12P as a mask. At this time, the pattern-forming thin film 11 of silicon nitride (SiNₓ) was patterned by dry etching using a fluorine-based gas (SF₆+He) as an etchant to form the thin film pattern 11P having the space pattern 11a. In the etching, anisotropic etching was successfully performed on the pattern-forming thin film 11 of silicon nitride (SiNₓ). Therefore, the opening width [W11] of the space pattern 11a formed in the thin film pattern 11P had a size comparable with the opening width [W12] of the first hard mask film 12, and the opening width [W11]=40 nm.

Thereafter, as shown in a step (4) of FIG. 8D, the first hard mask pattern 12P left on the thin film pattern 11P was removed by dry etching using oxygen-containing chlorine gas (Cl₂+O₂) as an etchant. Thus, the transfer mask of Comparative Example 1 was obtained in which the thin film pattern 11P of silicon nitride (SiNₓ) was formed on the transparent substrate 10 as a light-shielding pattern.

### Comparative Example 2

### [Preparation of Mask Blank (see FIG. 1, FIG. 7)]

As the mask blank 1 of Comparative Example 2, a mask blank for use in manufacturing a transmissive transfer mask was prepared. Here, after forming the first hard mask film 12 and before forming the resist film 14 in the mask blank manufacturing procedure of Comparative Example 1, reactive sputtering was performed in a gas mixture atmosphere of argon (Ar) and oxygen (O₂) using a tantalum (Ta) target to deposit tantalum oxide (TaOₓ) by sputtering with a film thickness of 3 nm as the second hard mask film 13. Thus, the mask blank 1 of Comparative Example 2 having the structure described with reference to FIG. 1 was prepared. In the second hard mask film 13, a ratio O/Ta of the content of oxygen (O) to the content of tantalum (Ta) was 2.5. That is, tantalum (Ta) in the second hard mask film 13 was saturated with oxygen. It may be said that the second hard mask film 13 was substantially formed of tantalum pentoxide (Ta₂O₅).

### [Preparation of Transfer Mask]

A method for manufacturing a transmissive transfer mask using the mask blank 1 of Comparative Example 2 will be described. The flow of the transfer mask manufacturing method in Comparative Example 2 is the same as that in FIGS. 2A-2C, 3A, and 3B except that the second hard mask film 13 does not swell. Therefore, description will be made with reference to FIGS. 2A-2C, 3A, and 3B.

First, the space pattern 14a having the opening width [W14]=34 nm was formed in the resist film 14 by lithography. The opening width [W14] is the minimum space width achieved by lithography for manufacture of the transmissive transfer mask at present.

Next, the second hard mask film 13 was etched using the patterned resist film 14 as a mask. At this time, the second hard mask film 13 of tantalum oxide (TaOₓ) was patterned by dry etching using a fluorine-based gas (SF₆+He) as an etchant to form the second hard mask pattern 13P having the space pattern 13a. In this etching, anisotropic etching was successfully performed on the second hard mask film 13 of tantalum oxide (TaOₓ). Therefore, the opening width [W13] of the space pattern 13a formed in the second hard mask pattern 13P had a size comparable with the opening width [W14] of the resist film 14, and the opening width [W13]=34 nm.

Thereafter, the first hard mask film 12 was etched using the second hard mask pattern 13P as a mask. At this time, the first hard mask film 12 of chromium nitride (CrNₓ) was patterned by dry etching using oxygen-containing chlorine gas (Cl₂+O₂) as an etchant to form the first hard mask pattern 12P having the space pattern 12a.

In this etching, although the second hard mask pattern 13P was exposed to the oxygen-containing chlorine gas (Cl₂+O₂), tantalum (Ta) contained in the second hard mask pattern 13P was not oxidized and the second hard mask pattern 13P did not swell. Therefore, after the first hard mask film 12 was etched, the opening width [W13] of the space pattern 13a of the second hard mask pattern 13P was kept at 34 nm.

Also, in this etching, the first hard mask film 12 of chromium nitride (CrNₓ) was isotropically etched. Therefore, the opening width [W12] of the space pattern 12a formed in the first hard mask pattern 12P was greater than the opening width [W13] of the space pattern 13a, and the opening width [W12]=38 nm. The resist film 14 left on the second hard mask pattern 13P was ashed and removed by the oxygen-containing etchant.

Next, the pattern-forming thin film 11 was etched using the first hard mask pattern 12P as a mask. At this time, the pattern-forming thin film 11 of silicon nitride (SiNₓ) was patterned by dry etching using a fluorine-based gas (SF₆+He) as an etchant to form the thin film pattern 11P having the space pattern 11a. In the etching, anisotropic etching was successfully performed on the pattern-forming thin film 11 of silicon nitride (SiNₓ). Therefore, the opening width [W11] of the space pattern 11a formed in the thin film pattern 11P had a size comparable with the opening width [W12] of the space pattern 12a in the first hard mask pattern 12P, and the opening width [W11]=40 nm.

Thereafter, the first hard mask pattern 12P left on the thin film pattern 11P was removed by dry etching using oxygen-containing chlorine gas (Cl₂+O₂) as an etchant. Thus, the transfer mask 100 of Comparative Example 2 was obtained in which the thin film pattern 11P of silicon nitride (SiNₓ) was formed on the transparent substrate 10 as a light-shielding pattern.

### Example 1

### [Preparation of Mask Blank (see FIG. 1, FIG. 7)]

As the mask blank 1 of Example 1, a mask blank for use in manufacturing a transmissive transfer mask was prepared. Here, after forming the first hard mask film 12 and before forming the resist film 14 in the mask blank manufacturing procedure of Comparative Example 1, reactive sputtering was performed in a gas mixture atmosphere of argon (Ar) and oxygen (O₂) using a tantalum (Ta) target to deposit tantalum oxide (TaOₓ) by sputtering with a film thickness of 3 nm as the second hard mask film 13. Thus, the mask blank 1 of Example 1 having the structure described with reference to FIG. 1 was prepared. In the second hard mask film 13, a ratio O/Ta of the content of oxygen (O) to the content of tantalum (Ta) was 1.3. Tantalum (Ta) in the second hard mask film 13 was unsaturated with oxygen.

### [Preparation of Transfer Mask (see FIGS. 2A-2C and 3A, 3B)]

A method for manufacturing a transmissive transfer mask using the mask blank 1 of Example 1 will be described with reference to FIGS. 2A-2C, 3A and 3B.

First, as shown in the step (1) of FIG. 2A, the space pattern 14a having the opening width [W14]=34 nm was formed in the resist film 14 by lithography. The opening width [W14] is the minimum space width achieved by lithography for manufacture of the transmissive transfer mask at present.

Next, as shown in the step (2) of FIG. 2B, the second hard mask film 13 was etched using the patterned resist film 14 as a mask. At this time, the second hard mask film 13 of tantalum oxide (TaOₓ) was patterned by dry etching using a fluorine-based gas (SF₆+He) as an etchant to form the second hard mask pattern 13P having the space pattern 13a. In this etching, anisotropic etching was successfully performed on the second hard mask film 13 of tantalum oxide (TaOₓ). Therefore, the opening width [W13] of the space pattern 13a formed in the second hard mask pattern 13P had a size comparable with the opening width [W14] of the resist film 14, and the opening width [W13]=34 nm.

Thereafter, as shown in the step (3) of FIG. 2C, the first hard mask film 12 was etched using the second hard mask pattern 13P as a mask. At this time, the first hard mask film 12 of chromium nitride (CrNₓ) was patterned by dry etching using oxygen-containing chlorine gas (Cl₂+O₂) as an etchant to form the first hard mask pattern 12P having the space pattern 12a.

In this etching, the second hard mask pattern 13P was exposed to the oxygen-containing chlorine gas (Cl₂+O₂) and the second hard mask pattern 13P swelled due to oxidation of tantalum (Ta) contained in the second hard mask pattern 13P. That is, the second hard mask film 13 in Example 1 had contained tantalum unsaturated with oxygen. Due to the oxidation of tantalum, the opening width [W13] of the space pattern 13a of the second hard mask pattern 13P became the opening width [W13′]=30 nm which had been reduced by swelling of the second hard mask pattern 13P.

Also, in this etching, the first hard mask film 12 of chromium nitride (CrNₓ) was isotropically etched. Therefore, the opening width [W12] of the space pattern 12a formed in the first hard mask pattern 12P was greater than the reduced opening width [W13′] of the space pattern 13a, and the opening width [W12]=34 nm. The resist film 14 left on the second hard mask pattern 13P was ashed and removed by the oxygen-containing etchant.

Next, as shown in the step (4) of FIG. 3A, the pattern-forming thin film 11 was etched using the first hard mask pattern 12P as a mask. At this time, the pattern-forming thin film 11 of silicon nitride (SiNₓ) was patterned by dry etching using a fluorine-based gas (SF₆+He) as an etchant to form the thin film pattern 11P having the space pattern 11a. In this etching, anisotropic etching was successfully performed on the pattern-forming thin film 11 of silicon nitride (SiNₓ). Therefore, the opening width [W11] of the space pattern 11a formed in the thin film pattern 11P had a size comparable with the opening width [W12] of the space pattern 12a in the first hard mask pattern 12P, and the opening width [W11]=36 nm.

Thereafter, as shown in the step (5) of FIG. 3B, the first hard mask pattern 12P left on the thin film pattern 11P was removed by dry etching using oxygen-containing chlorine gas (Cl₂+O₂) as an etchant. Thus, the transfer mask 100 of Example 1 was obtained in which the thin film pattern 11P of silicon nitride (SiNₓ) was provided on the transparent substrate 10 as a light-shielding pattern.

### Example 2

### [Preparation of Mask Blank (see FIG. 1, FIG. 7)]

As the mask blank 1 of Example 2, a mask blank for use in manufacturing a transmissive transfer mask was prepared. Here, after forming the first hard mask film 12 and before forming the resist film 14 in the mask blank manufacturing procedure of Comparative Example 1, reactive sputtering was performed in a gas mixture atmosphere of argon (Ar) and nitrogen (N₂) using a tantalum (Ta) target to deposit tantalum nitride (TaNₓ) by sputtering with a film thickness of 3 nm as the second hard mask film 13. Thus, the mask blank 1 of Example 2 having the structure described with reference to FIG. 1 was prepared. In the second hard mask film 13, a ratio O/Ta of the content of oxygen (O) to the content of tantalum (Ta) was 0. Tantalum (Ta) in the second hard mask film 13 was unsaturated with oxygen.

### [Preparation of Transfer Mask (see FIGS. 2A-2C, 3A, 3B)]

A transmissive transfer mask was prepared using the mask blank 1 of Example 2. Here, the same procedure as the preparation of the transfer mask in Example 1 was performed to obtain the transfer mask 100 of Example 1 having the thin film pattern 11P formed on the transparent substrate 10 by patterning the pattern-forming thin film 11 of silicon nitride (SiNₓ). Opening widths of the space patterns formed in the respective steps are shown in FIG. 7 together. In Example 2 also, when the first hard mask film 12 was etched using the second hard mask pattern 13P as a mask, the second hard mask pattern 13P swelled due to oxidation of tantalum (Ta) contained in the second hard mask pattern 13P. That is, the second hard mask film 13 had contained tantalum unsaturated with oxygen.

### Example 3

### [Preparation of Mask Blank (see FIGS. 4 and 7)]

As the mask blank of Example 3, the mask blank 2 for use in manufacturing a reflective transfer mask was prepared as follows.

First, the multilayer reflective film 21 was formed on the substrate 20 of low-expansion glass having a thickness of about 6.35 mm and the protective film 22 of a ruthenium-niobium alloy (RuNb) was formed on the multilayer reflective film 21. The multilayer reflective film 21 and the protective film 22 constituted an underlayer film. The underlayer film had a total film thickness of 289 nm.

On the underlayer film, tantalum nitride (TaNₓ) was deposited by sputtering as the first thin film 11-1 of the pattern-forming thin film 11′. Then, tantalum oxide (TaOₓ) was deposited by sputtering as the second thin film 11-2. A total film thickness of the first thin film 11-1 and the second thin film 11-2 was 62 nm.

On the pattern-forming thin film 11′, chromium oxide carbide nitride (CrOCN) was deposited by sputtering with a film thickness of 6 nm as the first hard mask film 12. Furthermore, reactive sputtering was performed in a gas mixture atmosphere of argon (Ar) and nitrogen (N₂) using a tantalum (Ta) target to deposit the second hard mask film 13 of tantalum nitride (TaNₓ) by sputtering with a film thickness of 3 nm. On the second hard mask film 13, a chemically amplified positive resist was deposited with a film thickness of 40 nm as the resist film 14 to obtain the mask blank 2 of Example 3. In the second hard mask film 13, a ratio O/Ta of the content of oxygen (O) to the content of tantalum (Ta) was 0. Tantalum (Ta) in the second hard mask film 13 was unsaturated with oxygen.

### [Preparation of Transfer Mask (see FIGS. 5A-5C, 6A and 6B)]

A method for manufacturing a reflective transfer mask using the mask blank 2 of Example 3 will be described with reference to FIGS. 5A-5C, 6A and 6B.

First, as shown in the step (1) of FIG. 5A, the space pattern 14a having the opening width [W14]=26 nm was formed in the resist film 14 by lithography. The opening width [W14] is the minimum space width achieved by lithography for manufacture of the reflective transfer mask at present.

Next, as shown in the step (2) of FIG. 5B, the second hard mask film 13 was etched using the patterned resist film 14 as a mask. At this time, the second hard mask film 13 of tantalum nitride (TaNₓ) was patterned by dry etching using a fluorine-based gas (SF₆+He) as an etchant to form the second hard mask pattern 13P having the space pattern 13a. In this etching, anisotropic etching was successfully performed on the second hard mask film 13 of tantalum nitride (TaNₓ). Therefore, the opening width [W13] of the space pattern 13a formed in the second hard mask pattern 13P had a size comparable with the opening width [W14] of the space pattern 14a formed in the resist film 14, and the opening width [W13]=26 nm.

Thereafter, as shown in the step (3) of FIG. 5C, the first hard mask film 12 was etched using the second hard mask pattern 13P as a mask. At this time, the first hard mask film 12 of chromium oxide carbide nitride (CrOCN) was patterned by dry etching using oxygen-containing chlorine gas (Cl₂+O₂) as an etchant to form the first hard mask pattern 12P having the space pattern 12a.

In this etching, the second hard mask pattern 13P was exposed to the oxygen-containing chlorine gas (Cl₂+O₂) and the second hard mask pattern 13P swelled due to oxidation of tantalum (Ta) contained in the second hard mask pattern 13P. That is, the second hard mask film 13 in Example 3 had contained tantalum unsaturated with oxygen. Due to the oxidation of tantalum, the opening width [W13] of the space pattern 13a of the second hard mask pattern 13P became the opening width [W13′]=20 nm which had been reduced by swelling of the second hard mask pattern 13P.

Also, in this etching, the first hard mask film 12 of chromium oxide carbide nitride (CrOCN) was isotropically etched. Therefore, the opening width [W12] of the space pattern 12a formed in the first hard mask pattern 12P was greater than the reduced opening width [W13′] of the space pattern 13a, and the opening width [W12]=24 nm. The resist film 14 left on the second hard mask pattern 13P was ashed and removed by the oxygen-containing etchant.

Next, as shown in the step (4) of FIG. 6A, the second thin film 11-2 of the pattern-forming thin film 11′ was etched using the first hard mask pattern 12P as a mask. At this time, the second thin film 11-2 of the pattern-forming thin film 11′ of tantalum oxide (TaOₓ) was patterned by dry etching using a fluorine-based gas (SF₆+He) as an etchant. In this etching, anisotropic etching was successfully performed on the second thin film 11-2 of tantalum oxide (TaOₓ). When the second thin film 11-2 was etched, the second hard mask pattern 13P, including the oxidized part 13b, was removed.

Subsequently, as shown in the step (5) of FIG. 6B, the first thin film 11-1 of the pattern-forming thin film 11′ was etched using the first hard mask pattern 12P as a mask. At this time, the first thin film 11-1 of the pattern-forming thin film 11′ of tantalum nitride (TaNₓ) was patterned by dry etching using chlorine gas (Cl₂) as an etchant. In this etching, anisotropic etching was successfully performed on the first thin film 11-1 of tantalum nitride (TaNₓ).

Thus, the thin film pattern 11P′ was formed by patterning the first thin film 11-1 and the second thin film 11-2 of the pattern-forming thin film 11′. The opening width [W11′] of the space pattern 11a′ formed in the thin film pattern 11P′ had a size comparable with the opening width [W12] of the first hard mask film 12, and the opening width [W11′]=26 nm. The first hard mask pattern 12P was removed by this etching.

In the above-mentioned manner, the reflective transfer mask 200 of Example 3 was obtained which had the thin film pattern 11P′, as a light-absorbing pattern, formed on the substrate 20 by patterning the pattern-forming thin film 11′ comprising a stacked structure of tantalum nitride (TaNₓ) and tantalum oxide (TaOₓ).

### Evaluation Results of Examples and Comparative Examples

As shown in FIG. 7, in the preparation of the transfer masks using the mask blanks of Examples 1-3, the opening widths [W11] and [W11′] of the respective space patterns 11a and 11a′ formed in the pattern-forming thin films 11 and 11′ were comparable with the opening width [W14] of the space pattern 14a formed in the resist film 14. Specifically, an increase rate of a width dimension from the opening width [W14] of the space pattern 14a formed in the resist film 14 was suppressed to a low value, 6% in Example 1 and 0% in Examples 2 and 3. It is noted here that the increase rate of the width dimension is a value (([W11]−[W14])/[W14] or ([W11′]−[W14])/[W14]) obtained by dividing a subtraction value, which is obtained by subtracting the opening width [W14] from the opening width [W11] or the opening width [W11′], by [W14]. In contrast, in the preparation of the transfer mask using the mask blank of Comparative Example 1, the opening width [W11] of the space pattern 11a formed in the pattern-forming thin film 11 was 6 nm greater than the opening width [W14] of the space pattern 14a formed in the resist film 14. That is, the increase rate of the width dimension in Comparative Example 1 had a large value of 18%. Similarly, in Comparative Example 2, the opening width [W11] of the space pattern 11a formed in the pattern-forming thin film 11 was 6 nm greater than the opening width [W14] of the space pattern 14a formed in the resist film 14, and the increase rate of the width dimension was 18%.

Thus, it has been confirmed that the mask blank to which the present disclosure is applied is capable of forming a fine space pattern in the pattern-forming thin film.

Furthermore, by comparing Example 1 and Example 2, there was confirmed an effect that the smaller the oxidized amount of tantalum (Ta) contained in the second hard mask film 13 is, the greater the swelling amount of the second hard mask pattern 13P is and the smaller the opening width [W13′] which has been reduced by swelling is. Furthermore, it has been confirmed that the swelling amount of the second hard mask pattern 13P can be controlled by the oxidized amount of tantalum (Ta) contained in the second hard mask film 13.

Furthermore, it has been confirmed that, by using the mask blank to which the present disclosure is applied, a transfer mask having a fine pattern can be manufactured and a semiconductor device prepared using the transfer mask manufactured in the above-mentioned manner can be highly integrated.

### DESCRIPTION OF REFERENCE SYMBOLS

1,2 . . . mask blank
10 . . . transparent substrate
11,11′ . . . pattern-forming thin film
11P, 11P′ . . . thin film pattern
12 . . . first hard mask film
12P . . . first hard mask pattern
13 . . . second hard mask film
13P . . . second hard mask pattern
20 . . . substrate
100, 200 . . . transfer mask

1. A mask blank comprising:
a substrate having a main surface;
a pattern-forming thin film on the main surface;
a first hard mask film on the pattern-forming thin film; and
a second hard mask film on the first hard mask film,
wherein the pattern-forming thin film contains at least one element selected from silicon and transition metals,
wherein the first hard mask film contains chromium,
wherein the second hard mask film contains tantalum,
wherein tantalum in the second hard mask film includes tantalum which is unsaturated with oxygen,
wherein the pattern-forming thin film has a film thickness of 20 nm or more,
wherein the first hard mask film has a film thickness of 15 nm or less, and
wherein the second hard mask film has a film thickness of 10 nm or less.

2. A mask blank comprising:
a substrate having a main surface;
a pattern-forming thin film on the main surface;
a first hard mask film on the pattern-forming thin film; and
a second hard mask film on the first hard mask film,
wherein the pattern-forming thin film contains at least one element selected from silicon and transition metals,
wherein the first hard mask film contains chromium,
wherein the second hard mask film contains tantalum,
wherein the pattern-forming thin film has a film thickness of 20 nm or more,
wherein the first hard mask film has a film thickness of 15 nm or less,
wherein the second hard mask film has a film thickness of 10 nm or less, and
wherein when the second hard mask film is etched to have a space pattern, an opening of the space pattern decreases in size when the space pattern is exposed to an oxygen-containing gas.

3. The mask blank according to claim 1,
wherein a ratio of an oxygen content to a tantalum content in the second hard mask film is 1.5 or less.

4. The mask blank according to claim 1,
wherein the second hard mask film comprises additional metal elements and/or silicon, and
wherein a tantalum content is greater than either the additional metal elements or silicon in the second hard mask film.

5. The mask blank according to claim 1,
wherein the second hard mask film has a film thickness of 1 nm or more.

6. The mask blank according to claim 1,
wherein the first hard mask film contains chromium and at least one of oxygen and nitrogen.

7. The mask blank according to claim 1,
wherein the first hard mask film has a film thickness greater than a thickness of the second hard mask film.

8. The mask blank according to claim 1,
wherein the pattern-forming thin film is a light-absorbing film containing tantalum, and
wherein the mask blank has a multilayer reflective film between the substrate and the pattern-forming thin film.

9. The mask blank according to claim 1,
wherein the pattern-forming thin film is a light-shielding film containing silicon.

10. (canceled)

11. (canceled)

12. The mask blank according to claim 2,
wherein a ratio of an oxygen content to a tantalum content in the second hard mask film is 1.5 or less.

13. The mask blank according to claim 2,
wherein the second hard mask film comprises additional metal elements and/or silicon, and
wherein a tantalum content is greater than either the additional metal elements or silicon in the second hard mask film.

14. The mask blank according to claim 2,
wherein the second hard mask film has a film thickness of 1 nm or more.

15. The mask blank according to claim 2,
wherein the first hard mask film contains chromium and at least one of oxygen and nitrogen.

16. The mask blank according to claim 2,
wherein the first hard mask film has a film thickness greater than a film thickness of the second hard mask film.

17. The mask blank according to claim 2,
wherein the pattern-forming thin film is a light-absorbing film containing tantalum, and
wherein the mask blank has a multilayer reflective film between the substrate and the pattern-forming thin film.

18. The mask blank according to claim 2,
wherein the pattern-forming thin film is a light-shielding film containing silicon.
